(19) United States
(12) Patent Application Publication
(10) Pub. No.: US 2023/0197592 A1
(43) Pub. Date: Jun. 22, 2023

(54) POWER DELIVERY TECHNIQUES FOR GLASS SUBSTRATE WITH HIGH DENSITY SIGNAL VIAS

(71) Applicant: Intel Corporation, Santa Clara, CA (US)

(72) Inventors: Telesphor KAMGAING, Chandler, AZ (US); Brandon RAWLINGS, Chandler, AZ (US); Aleksandar ALEKSOV, Chandler, AZ (US); Andrew P. COLLINS, Chandler, AZ (US); Georgios C. DOGIAMIS, Chandler, AZ (US); Veronica STRONG, Hillsboro, OR (US); Neelam PRABHU GAUNKAR, Chandler, AZ (US)

(21) Appl. No.: 17/553,189

(22) Filed: Dec. 16, 2021

(51) Int. Cl. H01L 23/498; H05K 1/18; H01L 23/15; H01L 21/48

(52) U.S. Cl. CPC H01L 23/49827; H01L 21/486; H01L 23/15; H01L 23/49822; H01L 23/49838; H05K 1/181

(57) ABSTRACT

Embodiments disclosed herein include electronic packages. In an embodiment, the electronic package comprises a core with a first surface and a second surface, where the core comprises glass. In an embodiment, a first buildup layer is over the first surface of the core, and a second buildup layer is under the second surface of the core. In an embodiment, the electronic package further comprises a via through the core between the first surface of the core and the second surface of the core, and a plane into the first surface of the core, where a width of the plane is greater than a width of the via.

### TECHNICAL FIELD

Embodiments of the present disclosure relate to electronic packages, and more particularly to electronic packages with a glass core that includes power delivery vias and planes.

### BACKGROUND

While glass core packages present a significant advantage for routing high-bandwidth vertical connections across the core, it also poses the challenge to simultaneously accommodate a thick metal layer for package level power delivery. Currently, in the case of traditional core materials (e.g., glass weave substrates, copper clad laminates), large and thick lateral power planes are provided on the core. However, currently available glass-weave package substrate core materials do not have the necessary dielectric constant and loss tangent at high frequencies that are necessary to route high-bandwidth connections. In addition, the techniques used to create vias in such glass-weave cores, as well as the composite nature of the cores, results in roughness at the metal-insulator (or metal-dielectric) sidewall interface that in turn results in insertion losses that are unsatisfactory for high-bandwidth signaling.

### BRIEF DESCRIPTION OF THE DRAWINGS

FIGS. 1A-1C are cross-sectional illustrations depicting a process for forming a via opening through a glass core with a laser-assisted etching process, in accordance with an embodiment.

FIGS. 2A-2C are cross-sectional illustrations depicting a process for forming blind via openings into a glass core with a laser-assisted etching process, in accordance with an embodiment.

FIGS. 3A-3C are cross-sectional illustrations depicting a process for forming a blind via opening into a glass core with a laser-assisted etching process, in accordance with an embodiment.

FIG. 4A is a cross-sectional illustration of a glass core with a power plane and a high-bandwidth via, in accordance with an embodiment.

FIG. 4B is a cross-sectional illustration of a glass core with a power plane with tapered sidewalls and a high-bandwidth via, in accordance with an embodiment.

FIG. 4C is a cross-sectional illustration of a glass core with a power plane above the glass core and a high-bandwidth via through the glass core, in accordance with an embodiment.

FIGS. 5A-5E are cross-sectional illustrations that depict a process for forming a core with a recessed power plane and a via through a thickness of the core, in accordance with an embodiment.

FIG. 6A is a cross-sectional illustration of a glass core with a plurality of power planes that are coupled together by a top metal layer, in accordance with an embodiment.

FIG. 6B is a cross-sectional illustration of a glass core with a plurality of power planes with tapered sidewalls that are coupled together by a top metal layer, in accordance with an embodiment.

FIG. 7A is a cross-sectional illustration of a plurality of power planes recessed into a glass core, in accordance with an embodiment.

FIG. 7B is a plan view illustration of the glass core in FIG. 7A, in accordance with an embodiment.

FIG. 8 is a cross-sectional illustration of a glass core with embedded power planes into both surfaces of the glass core, in accordance with an embodiment.

FIG. 9A is a cross-sectional illustration of a glass core with first power planes into a top surface of the glass core and second power planes into a bottom surface of the glass core, where the first power planes are held at a different voltage than the second power planes, in accordance with an embodiment.

FIG. 9B is a plan view illustration of the glass core in FIG. 9A, in accordance with an embodiment.

FIG. 10 is a cross-sectional illustration of an electronic system with a glass core in the package substrate that includes a power plane and a high-bandwidth via, in accordance with an embodiment.

FIG. 11 is a schematic of a computing device built in accordance with an embodiment.

### EMBODIMENTS OF THE PRESENT DISCLOSURE

Described herein are electronic packages with a glass core that includes power delivery vias and planes, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, currently available glass-weave package substrate core materials do not have the necessary dielectric constant and loss tangent at high frequencies that are necessary to route high-bandwidth connections. In addition, the techniques used to create vias in such glass-weave cores, as well as the composite nature of the cores, results in roughness at the metal-insulator sidewall interface that in turn results in insertion losses that are unsatisfactory for high-bandwidth signaling. Accordingly, embodiments disclosed herein include glass based cores. The glass based cores allow for smoother interfaces between the metal and the glass. Additionally, the glass includes the dielectric constant and loss tangent values necessary for high-bandwidth routing including high-speed IO vias for high speed signaling. As used herein, high-speed IO via may support large signal bandwidths for IO application such DC-28 GHz, DC-50 GHz, DC-100 GHz, etc. A high-speed IO via may even support high-speed bandpass interconnects (such mmWave/sub-THz interconnects) with several GHz of bandwidths in the spectrum from 100 GHz to 1000 GHz. Previously, it was difficult to integrate the power delivery features on the glass cores. However, embodiments disclosed herein include laser-assisted patterning processes that allow for the fabrication of such features. Particularly, the laser assisted patterning allows for the formation of vias through a thickness of the core and for cavities that are blind features (i.e., cavities that do not extend entirely through a thickness of the core).

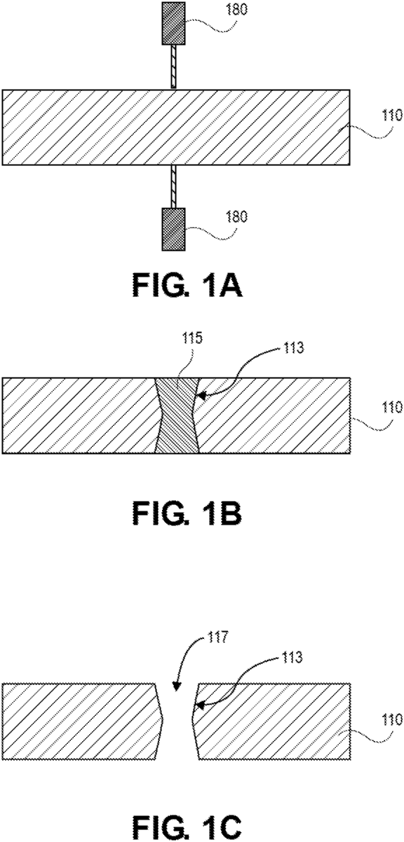

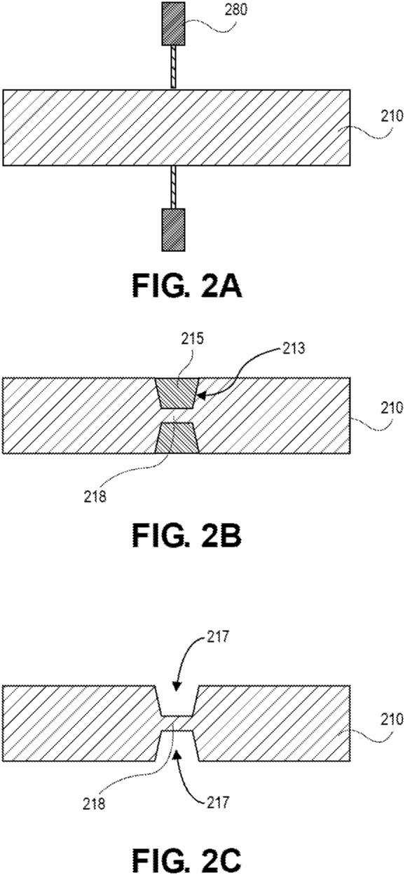

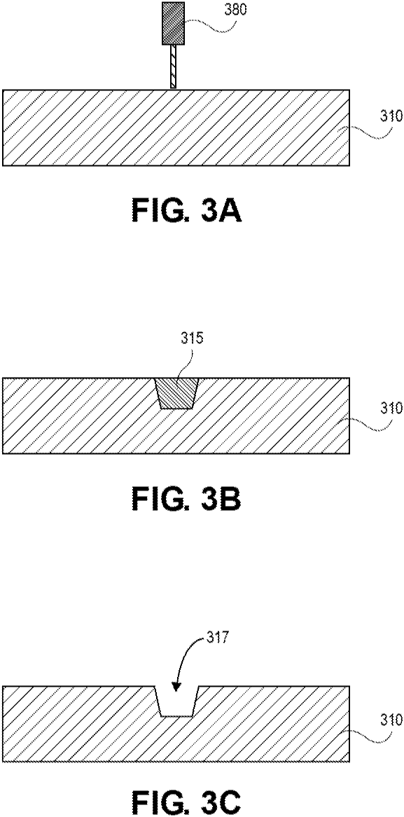

Referring now to FIGS. 1A-3C, three series of cross-sectional illustrations that depict processes for forming features in glass cores with laser assisted etching processes are shown, in accordance with an embodiment. In FIGS. 1A-1C, a through core via opening is formed. In FIGS. 2A-2C a pair of blind via openings on opposite surfaces of the core are formed. In FIGS. 3A-3C a blind via opening into the top surface of the core is formed. The openings formed in FIGS. 1A-3C can then be filled with materials (e.g., conductive materials) using various plating or other deposition processes.

Referring now to FIGS. 1A-1C, a series of cross-sectional illustrations depicting a process for fabricating openings in a glass core 110 is shown, in accordance with an embodiment.

Referring now to FIG. 1A, a cross-sectional illustration of a glass core 110 is shown, in accordance with an embodiment. In an embodiment, the glass core 110 may have a thickness that is between approximately 50 µm and approximately 1,000 µm. Though, it is to be appreciated that other thicknesses (larger or smaller) may also be used for the glass core 110. In an embodiment, a laser 180 is used to expose a region of the glass core 110. As shown in FIG. 1A, the exposure may be made on both sides (i.e., the top surface of the glass core 110 and the bottom surface of the glass core 110). A single laser 180 may be used, or multiple lasers may be used. In an embodiment, the laser 180 is exposed over the glass core 110 at locations where via openings are desired.

Referring now to FIG. 1B, a cross-sectional illustration of the glass core 110 after the laser 180 exposure is completed is shown, in accordance with an embodiment. As shown, the laser 180 exposure may result in the formation of exposed regions 115. In an embodiment, the glass core 110 may comprise a glass material that is able to be morphologically changed upon exposure to a laser 180. For example, the morphological change may result in the microstructure of the glass core 110 transforming to a crystalline structure from an amorphous structure. Accordingly, the exposed region 115 is shown with a different shading than the glass core 110.

In an embodiment, the laser 180 exposure may result in an exposed region 115 that has a tapered sidewall 113. In the instance where both sides of the glass core 110 are exposed (as is the case shown in FIG. 1A), the exposed region 115 may have a double tapered profile. That is, widths of the exposed region 115 at a top surface of the glass core 110 and at a bottom surface of the glass core 110 may be wider than a width at a middle of the glass core 110. In some instances, such a sidewall 113 profile may be referred to as an hourglass shaped profile.

Referring now to FIG. 1C, a cross-sectional illustration of the glass core 110 after the exposed region 115 is removed is shown, in accordance with an embodiment. In an embodiment, removal of the exposed region 115 may result in the formation of a via opening 117. The via opening 117 may pass entirely through a thickness of the glass core 110. In an embodiment, the via opening 117 may be a high aspect ratio via opening 117. As used herein a “high aspect ratio” may refer to an aspect ratio (depth:width) that is approximately 5:1 or greater, with the width being measured at a narrowest point through a thickness of the via opening 117. In other embodiments, the aspect ratio of the via opening 117 may be approximately 10:1 or greater, approximately 20:1 or greater, or approximately 50:1 or greater.

Referring now to FIGS. 2A-2C, a series of cross-sectional illustrations depicting a process for forming blind structures into a glass core 210 is shown, in accordance with an embodiment. Instead of forming an opening entirely through the glass core 210, structures that extend partially through a thickness of the core 210 are provided.

Referring now to FIG. 2A, a cross-sectional illustration of a glass core 210 is shown, in accordance with an embodiment. In an embodiment, the glass core 210 may be substantially similar to the glass core 110 described in greater detail above. For example, the glass core 210 may have a thickness between approximately 50 µm and approximately 1,000 µm. In an embodiment, lasers 280 may expose portions of the glass core 210. In an embodiment, the laser 280 exposure in FIG. 2A may be different than the laser 180 exposure in FIG. 1A. For example, an intensity or duration of the laser 280 exposure may be less than the intensity or duration of the laser 180 exposure in FIG. 1A.

Referring now to FIG. 2B, a cross-sectional illustration of the glass core 210 after exposed regions 215 are formed is shown, in accordance with an embodiment. In an embodiment, the exposed regions 215 do not extend entirely through a thickness of the glass core 210. For example, a region 218 may be provided between the top exposed region 215 and the bottom exposed region 215. In some instances, the exposed regions 215 still include tapered sidewalls 213. Since the exposed regions 215 are formed from only a single side, the sidewalls 213 may only have a single taper. That is, the exposed regions 215 may not be hourglass shaped.

Referring now to FIG. 2C, a cross-sectional illustration of the glass core 210 after the exposed regions 215 are removed to form openings 217 is shown, in accordance with an embodiment. In an embodiment, the exposed regions 215 may be removed with an etching process that is selective to the exposed regions 215 over the rest of the glass core 210. As shown, the openings 217 do not extend entirely through the glass core 210. In such embodiments, the openings 217 may be referred to as blind openings since they do not pass through the glass core 210.

Referring now to FIGS. 3A-3C, a series of cross-sectional illustrations depicting a process for forming a blind opening 317 is shown, in accordance with an embodiment.

Referring now to FIG. 3A, a cross-sectional illustration of a glass core 310 is shown, in accordance with an embodiment. In an embodiment, the glass core 310 may be substantially similar to the glass cores 110 and 210 described in greater detail above. For example, the glass core 310 may have a thickness between approximately 50 µm and approximately 1,000 µm. In an embodiment, a laser 380 may be used to expose a surface of the glass core 310. In contrast to embodiments described in greater detail above, the laser 380 exposure may only be provided on a single surface of the glass core 310.

Referring now to FIG. 3B, a cross-sectional illustration of the glass core 310 after the laser exposure to form an exposed region 315 is shown, in accordance with an embodiment. In an embodiment, the exposed region 315 may be a region that has a morphology change compared to the rest of the glass core 310. For example, the morphology change may be the transition from an amorphous structure to a crystalline structure. In an embodiment, the exposed region 315 may not extend entirely through a thickness of the glass core 310. That is, the exposed region 315 may be suitable for forming blind structures.

However, it is to be appreciated that in some embodiments, a laser 380 exposure on a single surface of the glass core 310 can be used to form an exposed region 315 that extends through an entire thickness of the glass core 310. That is, it is not necessary to use an exposure on both sides of the glass core 310 in order to form through core structures. In such an embodiment, the sidewall profile of the exposed region 315 may have a single taper, instead of the hour-glass shaped taper shown in FIG. 1B.

Referring now to FIG. 3C, a cross-sectional illustration of the glass core 310 after the exposed region 315 is removed is shown, in accordance with an embodiment. In an embodiment, the removal of the exposed region 315 may result in an opening 317 being formed into the surface of the glass core 310. In an embodiment, the opening 317 may be a blind opening. In other embodiments, the opening 317 may pass entirely through a thickness of the glass core 310.

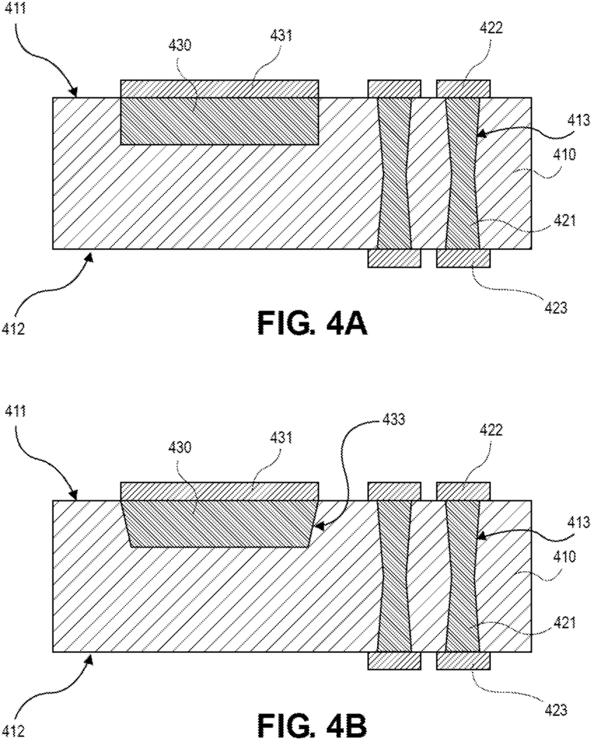

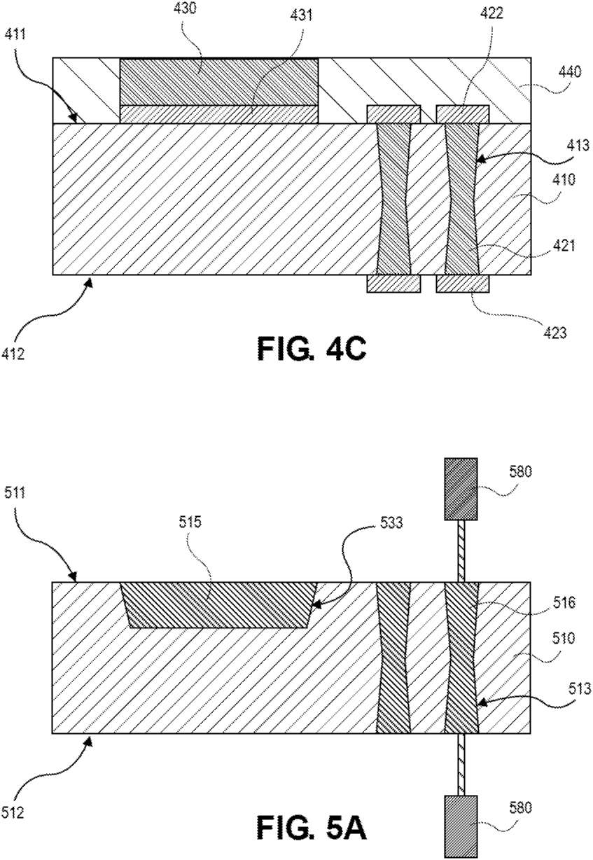

Referring now to FIG. 4A, a cross-sectional illustration of a glass core 410 is shown, in accordance with an embodiment. The glass core 410 may have a thickness between approximately 50 µm and approximately 1,000 µm, though thinner and thicker glass cores 410 may also be used. In an embodiment, the glass core 410 comprises a material that is suitable for laser assisted etching processes. For example, laser exposure of the glass core 410 results in a morphological change that allows for selective etching of the exposed regions.

In an embodiment, high-bandwidth vias 421 are provided through a thickness of the core 410. That is, the vias 421 extend from a first surface 411 of the core 410 to a second surface 412 of the core 410. In an embodiment, the vias 421 may comprise copper vias, though other conductive materials may also be used. In an embodiment, the vias 421 may have pads 422 over the first surface 411 and pads 423 over the second surface 412. In the illustrated embodiment, the pads 422 and 423 are shown with a different shading than the vias 421. However, it is to be appreciated that the vias 421 and the pads 422 and 423 may be the same material. Additionally, there may not be a discernable interface between the vias 421 and the pads 422 and 423. In a particular embodiment, the vias 421 may have a double tapered sidewall 413. For example, the tapered sidewall 413 may result in an hourglass shaped profile for the vias 421. In other embodiments, a single taper may be provided (e.g., when a single sided laser exposure of the via region is implemented).

In an embodiment, a power plane 430 may also be provided in the core 410. In an embodiment, the power plane 430 may extend into the first surface 411 of the core 410. However, the power plane 430 may not extend entirely through a thickness of the core 410. Instead, the power plane 430 may be a blind feature. In the illustrated embodiment, the power plane 430 extends approximately one-quarter the way through the core 410, but it is to be appreciated that the power plane 430 may have any thickness that is less than the thickness of the core 410. In an embodiment, a metal layer 431 may be provided above the power plane 430. The metal layer 431 protrudes up above the first surface 411. In the illustrated embodiment, the metal layer 431 and the power plane 430 are shown as having different shadings. However, in some embodiments, the power plane 430 and the metal layer 431 may be the same material. Additionally, there may be no discernable interface between the power plane 430 and the metal layer 431.

Referring now to FIG. 4B, a cross-sectional illustration of a glass core 410 is shown, in accordance with an additional embodiment. In an embodiment, the glass core 410 in FIG. 4B may be substantially similar to the glass core 410 in FIG. 4A, with the exception of the structure of the power plane 430. Instead of having substantially vertical sidewalls, the power plane 430 may have tapered sidewalls 433. The tapered sidewalls 433 may be the result of the laser exposure and etching process used to form the power plane 430. In an embodiment, the slope of the tapered sidewalls 433 of the power plane 430 may substantially match the slope of the sidewalls 413 of the vias 421.

Referring now to FIG. 4C, a cross-sectional illustration of a glass core 410 is shown, in accordance with an additional embodiment. In an embodiment, the glass core 410 in FIG. 4C may be substantially similar to the glass core 410 in FIG. 4A, with the exception of the location of the power plane 430. Instead of being positioned in a blind cavity into the glass core 410, the power plane 430 is provided in a buildup layer 440 over the first surface 411 of the core 410. In such an embodiment, the power plane 430 may be above the metal layer 431.

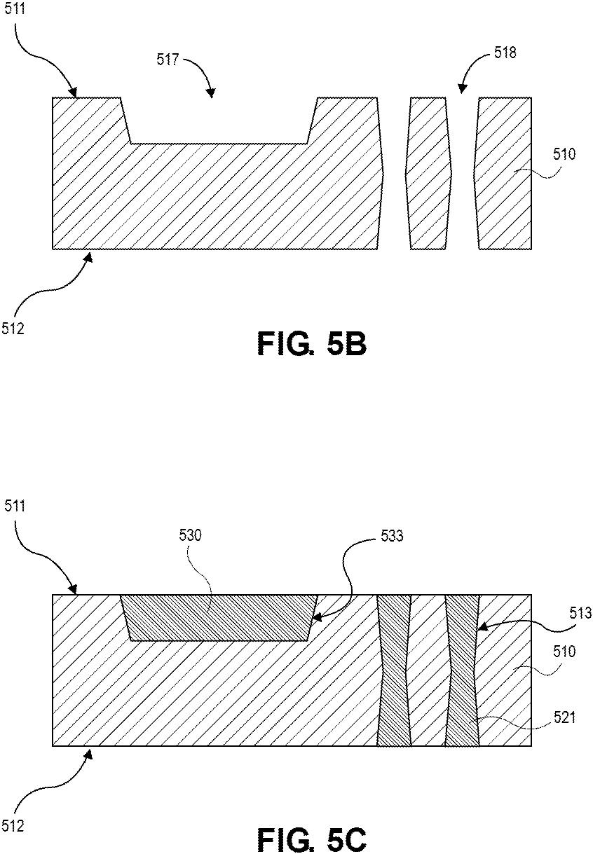

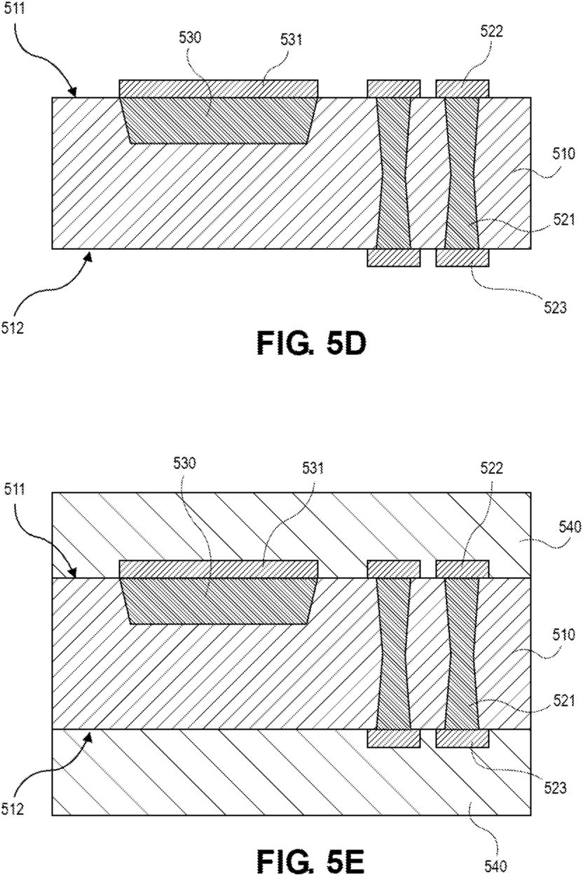

Referring now to FIGS. 5A-5E, a series of cross-sectional illustrations depicting a process for forming a glass core with high-bandwidth vias and an embedded power plane is shown, in accordance with an embodiment.

Referring now to FIG. 5A, a cross-sectional illustration of a glass core 510 that is being exposed by a laser 580 is shown, in accordance with an embodiment. In an embodiment, the glass core 510 may be substantially similar to any of the glass cores described in greater detail above. In an embodiment, the laser 580 may expose a first surface 511 and a second surface 512 of the core 510. In a particular embodiment, a power plane region 515 is formed with a laser 580 exposure of a single surface of the core 510 (i.e., the first surface 511), and the via regions 516 are formed with a laser 580 exposure of both the first surface 511 and the second surface 512. Since a single sided exposure is used to form the power plane region 515, the sidewall 533 has a single taper. Since a double sided exposure is used to form the via regions 516, a double taper (i.e., an hourglass shaped profile) is provided on the sidewalls 513. However, it is to be appreciated that the via regions 516 may alternatively be formed with a single sided exposure. In such an embodiment, the laser power and duration of exposure will define if the complete thickness of the glass is modified. The etching will then start from both sides, leading to a via shape with an hourglass profile.

Referring now to FIG. 5B, a cross-sectional illustration of the glass core 510 after the power plane region 515 and the via regions 516 are removed is shown, in accordance with an embodiment. In an embodiment, removal of the power plane region 515 results in the formation of a power plane opening 517. The power plane opening 517 extends into the first surface 511 of the core 510, but does not pass entirely through the core 510. That is, the power plane opening 517 is a blind feature. In contrast, the removal of the via regions 516 result in via openings 518 that pass entirely through a thickness of the core 510 from the first surface 511 to the second surface 512.

Referring now to FIG. 5C, a cross-sectional illustration of the glass core 510 after the power plane 530 and the vias 521 are formed is shown, in accordance with an embodiment. In an embodiment, the power plane 530 and the vias 521 may be disposed in the openings with a plating process. For example, a seed layer (not shown) may first be formed and the power plane 530 and the vias 521 may be plated up from the seed layer. Though, it is to be appreciated that other plating or deposition processes may also be used in accordance with various embodiments.

Referring now to FIG. 5D, a cross-sectional illustration of the glass core 510 after the metal layer 531 and pads 522 and 523 are formed is shown, in accordance with an embodiment. In an embodiment, the metal layer 531 and the pads 522 and 523 may be plated using the seed layer and subsequently patterned. In other embodiments, the shape of the metal layer 531 and the pads 522 and 523 may be defined by a resist layer (not shown), and the plating may be performed through the openings in the resist layer. The resist layer and any exposed seed layer may be removed after the formation of the metal layer 531 and the pads 522 and 523. In other embodiments, the power plane 530, the metal layer 531, the vias 521, and the pads 522 and 523 may be plated with a single plating process.

Referring now to FIG. 5E, a cross-sectional illustration of the glass core 510 after the addition of buildup layers 540 is shown, in accordance with an embodiment. In an embodiment, a first buildup layer 540 may be added over the first surface 511, and a second buildup layer 540 may be added over the second surface 512. The buildup layers 540 may be formed with a lamination process or the like. In an embodiment, conductive routing (e.g., pads, traces, vias, etc.) may be fabricated in the buildup layers 540 in order to provide routing to a die over the first surface 511 and a board under the second surface 512.

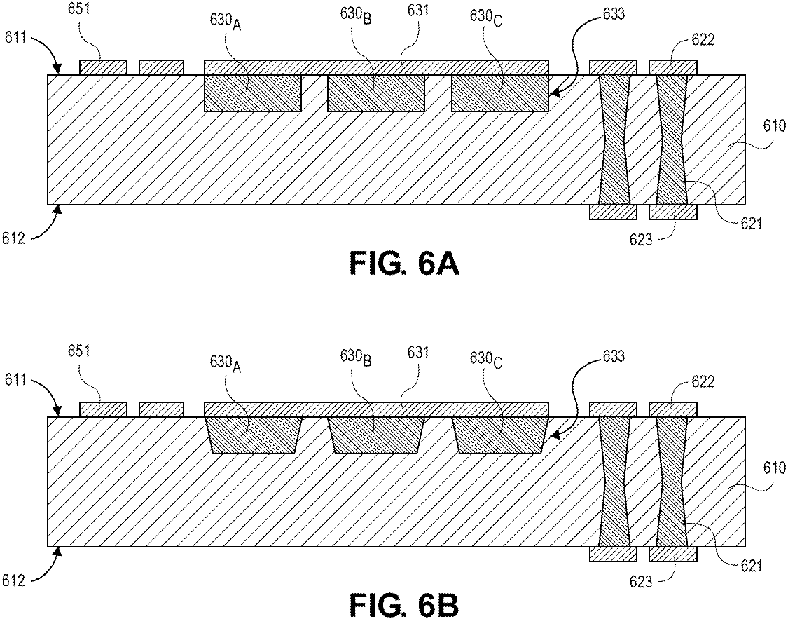

Referring now to FIG. 6A, a cross-sectional illustration of a core 610 is shown, in accordance with an additional embodiment. In the illustrated embodiment, vias 621 may be provided through a thickness of the core 610 between a first surface 611 and a second surface 612. Pads 622 and 623 may be provided above and below the vias 621. In an embodiment, traces 651 may also be provided over the first surface 611.

In an embodiment, the core 610 may include a plurality of via planes 630. For example, three via planes 630_{A} - 630_{C} are shown in FIG. 6A. The via planes 630 may be blind features that extend into, but not through, a thickness of the core 610. The via planes 630 may be electrically coupled to each other by a metal layer 631 over the first surface 611 of the core 610. In an embodiment, the via planes 630 may each have substantially vertical sidewalls 633.

Referring now to FIG. 6B, a cross-sectional illustration of a core 610 is shown, in accordance with an additional embodiment. In an embodiment, the core 610 may be substantially similar to the core 610 in FIG. 6A, with the exception of the structure of the power planes 630. Instead of having vertical sidewalls 633, the embodiment shown in FIG. 6B includes sidewalls 633 that are tapered. The tapered structure of the sidewalls 633 may be a remnant of the laser-assisted etching process used to form the power planes 630.

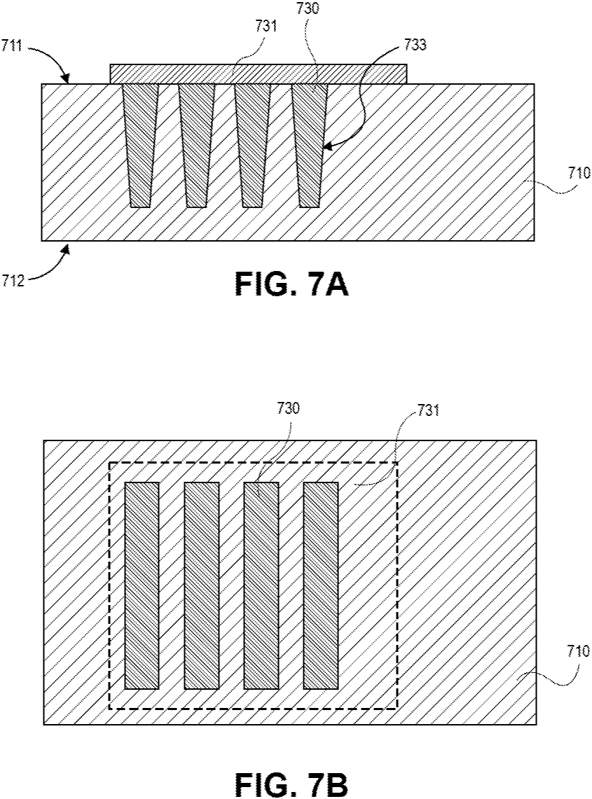

Referring now to FIG. 7A, a cross-sectional illustration of a core 710 is shown, in accordance with an additional embodiment. As shown, a plurality of power planes 733 may extend into the first surface 711 of the core 710. The power planes 730 may extend past the midway point (in the thickness direction). However, the power planes 730 do not extend to the second surface 712. In the illustrated embodiment, the power planes 730 may be electrically coupled together by a metal layer 731 over the first surface 711 of the core 710. The power planes 730 may have tapered sidewalls 733.

In the cross-sectional illustration, the power planes 730 may appear similar to vias. However, it is to be appreciated that the laser-assisted etching process allows for the power planes 730 to be extended into and out of the plane of FIG. 7A. For example, in FIG. 7B, a plan view illustration of the core 710 is shown. The metal layer 731 is shown with a dashed line to indicate it is hidden. The metal layer 731 may be a solid plane or a meshed plane. As shown, each of the power planes 730 are extended in order to form a plane like structure.

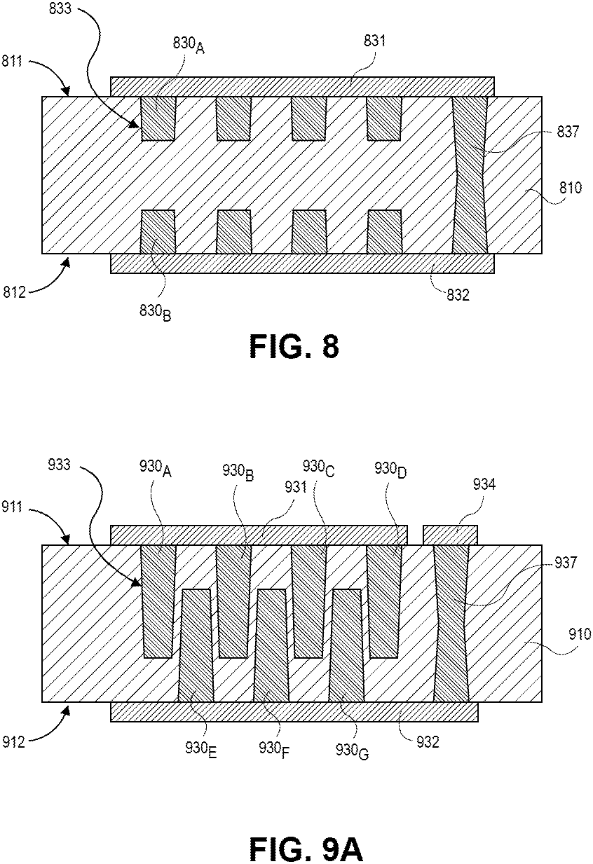

Referring now to FIG. 8, a cross-sectional illustration of a core 810 is shown, in accordance with another embodiment. As shown, power planes 830 may be formed into the top surface 811 and the bottom surface 812 of the core 810. In an embodiment, a via 837 may electrically couple together a metal layer 831 and a metal layer 832. The metal layer 831 electrically couples together the top power planes 830_{A}, and the metal layer 832 electrically couples together the bottom power planes 830_{B}. As such, the top power planes 830_{A} and the bottom power planes 830_{B} may be held at the same potential in some embodiments.

In the illustrated embodiment, the top power planes 830_{A} are directly over the bottom power planes 830_{B}. In other embodiments, the top power planes 830_{A} may be offset from the bottom power planes 830_{B}. Additionally, there may be a different number of top power planes 830_{A} and bottom power planes 830_{B}. The power planes 830 may have tapered sidewalls 833. The taper of the sidewalls 833 may be oriented so that the power planes 830 are narrower closer to the middle of the core 810 compared to at the surfaces 811 and 812. This results in the top power planes 830_{A} having a taper that is opposite in direction compared to the taper of the bottom power planes 830_{B}.

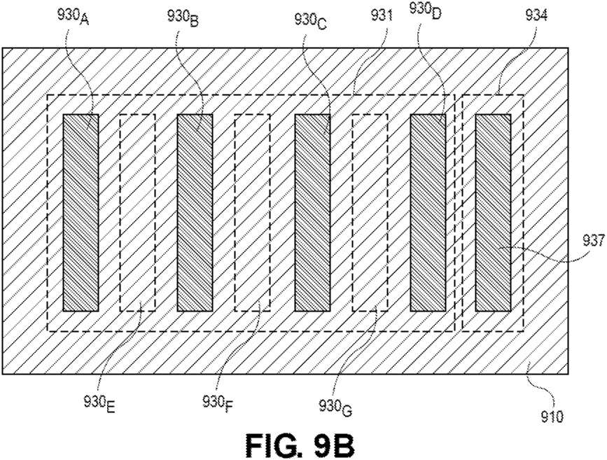

Referring now to FIG. 9A, a cross-sectional illustration of a core 910 is shown, in accordance with an additional embodiment. As shown, the core 910 comprises top power rails 930_{A-D} and bottom power rails 930_{E-G} The top power rails 930_{A-D} may be offset from the bottom power rails 930_{E-G}. Additionally, the top power rails 930_{A-D} may overlap (in the Z-dimension) the bottom power rails 930_{E-G}. That is, portions of the top power rails 930_{A-D} may be laterally adjacent to portions of the bottom power rails 930_{E-G}.

In an embodiment, the top power rails 930_{A-D} may be coupled together by a metal layer 931, and the bottom power rails 930_{E-G} may be coupled together by a metal layer 932. The metal layer 932 may be coupled to a top surface 911 by a via 937 that ends at pad 934. In some embodiments, via 937 is a power rail. In an embodiment, the top power rails 930_{A-D} and the bottom power rails 930_{E-G} may be held at different electrical potentials. For example, the top power rails 930_{A-D} may be held at V_{dd} and the bottom power rails 930_{E-G} may be held at Vₛₛ.

Referring now to FIG. 9B, a plan view illustration of the core 910 in FIG. 9A is shown, in accordance with an embodiment. As shown, the top power rails 930_{A-D}, the bottom power rails 930_{E-G}, and the via 937 may extend laterally to form plane like structures. The bottom power rails 930_{E-G} are shown with dashed lines to indicate that they do not extend to the top surface shown in FIG. 9B. The metal layer 931 and pad 934 are also shown with dashed lines in order to see the underlying structures.

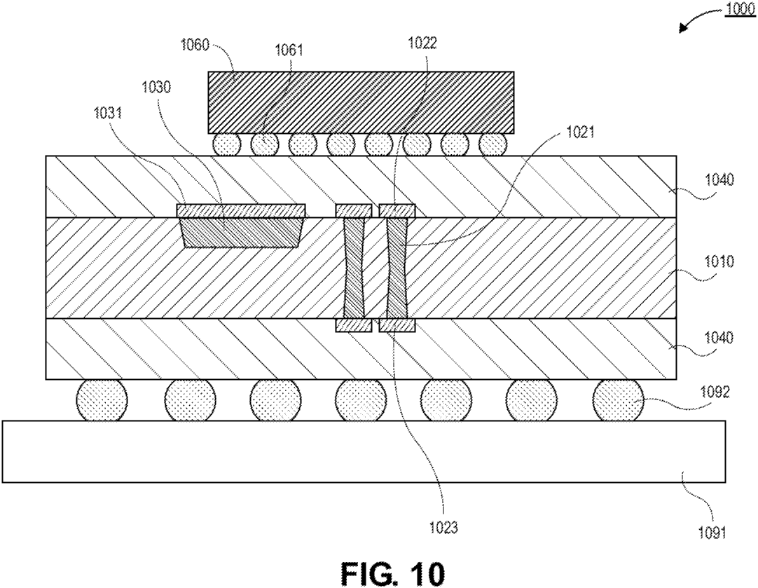

Referring now to FIG. 10, a cross-sectional illustration of an electronic system 1000 is shown, in accordance with an embodiment. In an embodiment, the electronic system 1000 comprises a board 1091, such as a printed circuit board (PCB). In an embodiment, the board is coupled to a package substrate by interconnects 1092. The interconnects 1092 are shown as solder balls, but it is to be appreciated that any suitable interconnect architecture may be used. In an embodiment, the package substrate comprises a glass core 1010 and buildup layers 1040 above and/or below the core 1010.

In an embodiment, the glass core 1010 comprises a power plane 1030 and high-bandwidth vias 1021. A metal layer 1031 may be above the power plane 1030, and pads 1022 and 1023 may be above and below the vias 1021. In an embodiment, the power plane 1030 is a blind feature. That is, the power plane 1030 does not extend entirely through a thickness of the core 1010.

In an embodiment, a die 1060 may be coupled to the buildup layer 1040 by interconnects 1061. The interconnects 1061 are shown as solder balls, but it is to be appreciated that any interconnect architecture may be used. In an embodiment, the die 1060 is a processor. Though it is to be appreciated that any die functionality may be implemented by the die 1060 and/or there may be a plurality of dies 1060.

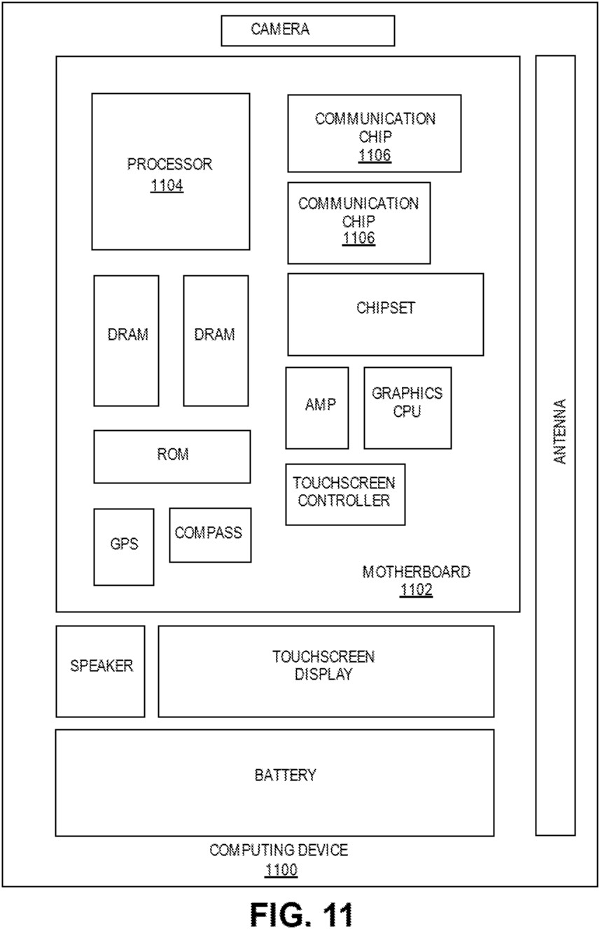

FIG. 11 illustrates a computing device 1100 in accordance with one implementation of the invention. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1104. In some implementations of the invention, the integrated circuit die of the processor may be part of an electronic package that comprises a glass core with blind power planes and high-bandwidth vias, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation of the invention, the integrated circuit die of the communication chip may be part of an electronic package that comprises a glass core with blind power planes and high-bandwidth vias, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a core with a first surface and a second surface, wherein the core comprises glass; a first buildup layer over the first surface of the core; a second buildup layer under the second surface of the core; a via through the core between the first surface of the core and the second surface of the core; and a recess into the first surface of the core and filled with a metal, wherein a width of the recess is greater than a width of the via.

Example 2: an electronic package of Example 1, wherein the recess comprises tapered sidewalls.

Example 3: the electronic package of Example 1 or Example 2, wherein the via comprises an hourglass shaped cross-section.

Example 4: the electronic package of Examples 1-3, wherein a top surface of the recess is substantially coplanar with the first surface of the core.

Example 5: the electronic package of Example 4, further comprising: a surface metal over the recess on the first surface of the core; and a pad over the via on the first surface of the core.

Example 6: the electronic package of Examples 1-5, wherein the recess extends past a midpoint of the core in a thickness direction.

Example 7: the electronic package of Examples 1-6, further comprising: a plurality of recesses into the first surface of the core, wherein the plurality of recesses are substantially parallel to each other.

Example 8: the electronic package of Example 7, further comprising: a second plurality of recesses into the second surface of the core, wherein the second plurality of recesses are interdigitated with the plurality of recesses.

Example 9: the electronic package of Example 8, wherein the plurality of recesses are coupled together by a first metal layer on the first surface of the core, and wherein the second plurality of recesses are coupled together by a second metal layer on the second surface of the core.

Example 10: a method of forming an electronic package comprising: providing a core, wherein the core is a glass substrate with a first surface and a second surface; exposing the first surface and the second surface with a laser to form exposed regions, wherein the exposed regions comprise: a plane region; and a via region; etching the exposed regions to form a plane opening and a via opening; and filling the plane opening and the via opening with a conductive material to form a plane and a via.

Example 11: the method of Example 10, wherein the plane region is formed by exposing only the first surface of the core, and wherein the via region is formed by exposing the first surface of the core and the second surface of the core.

Example 12: the method of Example 10 or Example 11, wherein the plane has tapered sidewalls.

Example 13: the method of Examples 10-12, wherein the via has tapered sidewalls.

Example 14: the method of Example 13, wherein the via has an hourglass shaped profile.

Example 15: the method of Examples 10-14, wherein a width of the plane is greater than a width of the via.

Example 16: the method of Examples 10-15, wherein the plane extends into the core past a midpoint of the core in a thickness direction.

Example 17: the method of Examples 10-16, wherein the via is a high speed IO via.

Example 18: the method of Examples 10-17, further comprising: forming a metal layer over the plane on the first surface of the core.

Example 19: the method of Examples 10-18, further comprising: forming pads above and below the via.

Example 20: an electronic package, comprising: a core with a first surface and a second surface, wherein the core is a glass substrate; a first buildup layer over the first surface of the core; a second buildup layer under the second surface of the core; power delivery features embedded within a thickness of the core, wherein the power delivery features comprise a plurality of conductive planes; and a via through a thickness of the core.

Example 21: the electronic package of Example 20, wherein the plurality of conductive planes extend into the first surface of the core, and wherein the plurality of conductive planes do not pass entirely through the thickness of the core.

Example 22: the electronic package of Example 20 or Example 21, wherein individual ones of the plurality of conductive planes have tapered sidewalls.

Example 23: the electronic package of Examples 20-22, wherein the via has an hourglass shaped profile.

Example 24: an electronic system, comprising: a board; a package substrate coupled to the board, wherein the package substrate comprises: a core with a first surface and a second surface, wherein the core comprises glass; a first buildup layer over the first surface of the core; a second buildup layer under the second surface of the core; a via through the core between the first surface of the core and the second surface of the core; and a plane into the first surface of the core, wherein a width of the plane is greater than a width of the via; and a die coupled to the package substrate.

Example 25: the electronic system of Example 24, wherein the plane comprises tapered sidewalls.

What is claimed is:

1. An electronic package, comprising:
a core with a first surface and a second surface, wherein the core comprises glass;
a first buildup layer over the first surface of the core;
a second buildup layer under the second surface of the core;
a via through the core between the first surface of the core and the second surface of the core; and
a recess into the first surface of the core and filled with a metal, wherein a width of the recess is greater than a width of the via.

2. The electronic package of claim 1, wherein the recess comprises tapered sidewalls.

3. The electronic package of claim 1, wherein the via comprises an hourglass shaped cross-section.

4. The electronic package of claim 1, wherein a top surface of the recess is substantially coplanar with the first surface of the core.

5. The electronic package of claim 4, further comprising:
a surface metal over the recess on the first surface of the core; and
a pad over the via on the first surface of the core.

6. The electronic package of claim 1, wherein the recess extends past a midpoint of the core in a thickness direction.

7. The electronic package of claim 1, further comprising:
a plurality of recesses into the first surface of the core, wherein the plurality of recesses are substantially parallel to each other.

8. The electronic package of claim 7, further comprising:
a second plurality of recesses into the second surface of the core, wherein the second plurality of recesses are interdigitated with the plurality of recesses.

9. The electronic package of claim 8, wherein the plurality of recesses are coupled together by a first metal layer on the first surface of the core, and wherein the second plurality of recesses are coupled together by a second metal layer on the second surface of the core.

10. A method of forming an electronic package comprising:
providing a core, wherein the core is a glass substrate with a first surface and a second surface;
exposing the first surface and the second surface with a laser to form exposed regions, wherein the exposed regions comprise:
a plane region; and
a via region;
etching the exposed regions to form a plane opening and a via opening; and
filling the plane opening and the via opening with a conductive material to form a plane and a via.

11. The method of claim 10, wherein the plane region is formed by exposing only the first surface of the core, and wherein the via region is formed by exposing the first surface of the core and the second surface of the core.

12. The method of claim 10, wherein the plane has tapered sidewalls.

13. The method of claim 10, wherein the via has tapered sidewalls.

14. The method of claim 13, wherein the via has an hourglass shaped profile.

15. The method of claim 10, wherein a width of the plane is greater than a width of the via.

16. The method of claim 10, wherein the plane extends into the core past a midpoint of the core in a thickness direction.

17. The method of claim 10, wherein the via is a high speed IO via.

18. The method of claim 10, further comprising:
forming a metal layer over the plane on the first surface of the core.

19. The method of claim 10, further comprising:
forming pads above and below the via.

20. An electronic package, comprising:
a core with a first surface and a second surface, wherein the core is a glass substrate;
a first buildup layer over the first surface of the core;
a second buildup layer under the second surface of the core;
power delivery features embedded within a thickness of the core, wherein the power delivery features comprise a plurality of conductive planes; and
a via through a thickness of the core.

21. The electronic package of claim 20, wherein the plurality of conductive planes extend into the first surface of the core, and wherein the plurality of conductive planes do not pass entirely through the thickness of the core.

22. The electronic package of claim 20, wherein individual ones of the plurality of conductive planes have tapered sidewalls.

23. The electronic package of claim 20, wherein the via has an hourglass shaped profile.

24. An electronic system, comprising:
a board;
a package substrate coupled to the board, wherein the package substrate comprises:
a core with a first surface and a second surface, wherein the core comprises glass;
a first buildup layer over the first surface of the core;
a second buildup layer under the second surface of the core;
a via through the core between the first surface of the core and the second surface of the core; and
a plane into the first surface of the core, wherein a width of the plane is greater than a width of the via; and
a die coupled to the package substrate.

25. The electronic system of claim 24, wherein the plane comprises tapered sidewalls.
